(19) United States
(12) Patent Application Publication
(10) Pub. No.: US 2010/0294432 A1
(43) Pub. Date: Nov. 25, 2010

(54) Plasma Processing Apparatus

(76) Inventors: Manabu EDAMURA, Chiyoda (JP); Ken YOSHIOKA, Hikari (JP); Takeshi SHIMADA, Hikari (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 12/850,664

(22) Filed: Aug. 5, 2010

Related U.S. Application Data
(63) Continuation of application No. 11/066,223, filed on Feb. 28, 2005.

(30) Foreign Application Priority Data
Feb. 7, 2005 (JP) 2005-030674

(51) Int. Cl. H01L 21/44

(52) U.S. Cl. 156/345.33

(57) ABSTRACT

A plasma processing apparatus, a processing chamber having one surface formed by a flat-plate-like insulating-material manufactured window, a sample mounting electrode having a sample mounting plane formed on a surface opposed to the insulating-material manufactured window, a gas-inlet for a flat-plate-structured capacitively coupled antenna formed on an outer surface of the insulating-material manufactured window with slits provided in a radial pattern, an inductively coupled antenna formed outside OF the insulating-material manufactured window and performing an inductive coupling with a plasma via the window, the plasma being formed within the processing chamber, a radio-frequency power supply, and an LC circuit. The inductively coupled antenna is configured by a coil which is wound a plurality of times with a direction defined as a longitudinal direction, the direction extending perpendicular to the sample mounting plane.

### CROSS REFERENCE TO RELATED APPLICATION

This application is a continuation of U.S. application Ser. No. 11/066,223, filed Feb. 28, 2005, the contents of which are incorporated herein by reference.

### BACKGROUND OF THE INVENTION

1. Field of the Invention

The present invention relates to a plasma processing apparatus. More particularly, it relates to a plasma processing apparatus which is capable of generating a stable and uniform plasma.

2. Description of the Related Art

In recent years, in conventional LSI devices as well as in novel memory devices such as FeRAM (Ferroelectric Random Access Memory) and MRAM (Magnetoresistive Random Access Memory), much use has been made of materials such as precious metals, e.g., Pt and Ir, magnetic materials, and non-volatile materials.

For example, a capacitor unit for storing bit information in FeRAM is configured such that a ferroelectric material such as PZT (Pb(Ti, Zr)O₃) or SBT (SrBi₂Ta₂O₉) is sandwiched between electrodes of the precious metals such as Ir, Ru, or Pt. These precious metals are considerably unlikely to form high-volatility reaction products. Accordingly, it is extremely difficult to perform an etching processing for these materials.

When forming microscopic electrodes and wirings by performing patterning of these Pt or Fe-containing materials, there is performed a plasma etching which basically uses halogen-containing gases such as chlorine gas. In the development of LSI fabrication technologies, the plasma etching has played an important role as the technology for performing patterning of mainly Si, SiO₂, and Al-based wiring films. These materials of Si, SiO₂, and Al can be removed as follows: Namely, by using chlorine-, fluorine-, or bromine-containing gases, these materials are caused to react with these gases to produce reaction products. Then, the reaction products produced are removed by a pump.

However, the above-described materials such as Pt and Fe, which are materials to be newly introduced from now on, exhibit only a low reactivity with the halogen-containing gases. Simultaneously, vapor pressures of these materials' halides, i.e., the resultant reaction products, are small. Namely, these novel materials exhibit characteristics that the etching rates are small, and that adhesions of the reaction products are extremely high.

Here, the following findings have been well known: Namely, in order to etch these non-volatile materials, it is effective to introduce high-energy ions under a high-bias condition. Moreover, in order to promote sublimation of the resultant reaction products, it is effective to maintain a wafer to be processed at a high temperature. For example, Hyoun-woo Kim (J. Vac. Sci. Technol. A17, 1999, 2151) has shown that, when etching Pt by using Cl₂/O₂ gas, maintaining the wafer at a high temperature of 220° C. allows implementation of the etching with a sharp taper angle and better configuration.

In this way, at the experimental and prototype level, it has been confirmed that the employment of the high-temperature and high-bias condition permits the better implementation of patterning of these non-volatile materials by the plasma etching. Simultaneously, the novel LSI devices using these materials are now being prototyped. It is not at all easy, however, to implement the plasma etching of these non-volatile materials at a mass-production level. The reason for this is as follows: The reaction products produced during the plasma etching processing of these non-volatile materials exhibit low vapor pressures. As a result, most of the reaction products turns out to be deposited onto inner-wall surface of the chamber without being exhausted by the pump. At the experimental and prototype level, no specific problems exist. In the LSI mass-production, however, performing the plasma etching processing of these non-volatile materials results in the following situation: Namely, in the processing number at a several-piece to several-tens-of-piece level, a deposition film due to the reaction products is deposited thickly onto the inner-wall surface of the chamber. This deposition film changes the plasma state, or generates particles, thereby making the plasma etching processing difficult. In order to implement an etching apparatus for the non-volatile materials which is applicable to the mass-production line, countermeasures against this deposition film become the most important issue.

At present, in the general semiconductor-device fabrication process, an inductively-coupled plasma processing apparatus is often used for the plasma etching processing. The inductively-coupled plasma processing apparatus is a plasma apparatus based on the following scheme: A loop-like inductively coupled antenna is located outside a processing chamber near a window. This window is formed of an insulating material such as alumina or quartz, and configures a part of the processing chamber. Moreover, a radio-frequency power is fed to this inductively coupled antenna, thereby supplying energy to a process gas introduced into the processing chamber, and thus maintaining the plasma.

An advantage of the inductively-coupled plasma processing apparatus is as follows: Namely, with a simple and inexpensive configuration including only the inductively coupled antenna and a radio-frequency power supply, it is possible to generate the plasma exhibiting a comparatively high density of 1×10¹¹ to 1×10¹² (cm⁻³) under a low pressure of 0.1 Pa order.

In the plasma etching of the non-volatile materials such as Pt and Fe, however, the electrically-conductive reaction products are deposited to the alumina or quartz window near the inductively coupled antenna as the plasma etching processings are repeated. As a consequence, the power fed to the inductively coupled antenna becomes less likely to be absorbed by the plasma. This decreases the plasma density, thereby giving rise to a decrease in the etching rate, or increasing the number of particles flying over onto the wafers.

In order to solve the problems of this kind, in, e.g., JP-A-2000-323298, the following method has been disclosed: Namely, an electrically conductive member is located in such a manner that this member will cover the insulating-material manufactured window, i.e., the portion into which the power of the inductively coupled antenna is injected. In this electrically conductive member, slits are provided (in a radial pattern) in such a manner that the slits will cut across loops of the inductively coupled antenna. Then, the radio-frequency power is applied to this electrically conductive member. This makes it possible to increase energy of the ions incoming into the inner surface of the insulating-material manufactured window, thereby preventing the deposition of the reaction products onto the insulating-material manufactured window.

This electrically conductive member, which is connected to the ground potential, has basically the same configuration as that of the Faraday shield used for the purpose of preventing the voltage at the inductively coupled antenna from exerting influences on the plasma. A desired radio-frequency power, however, is applicable to the electrically conductive member in which the above-described slits are provided. This is made possible by, e.g., branching a power from line of the radio-frequency power applied to the inductively coupled antenna. In this way, it has been recognized that, by applying the voltage to the slits-equipped electrically conductive member (i.e., capacitively coupled antenna), it becomes possible to acquire the stable etching processing even in the etching process of the non-volatile materials. This finding has been shown in, e.g., Manabu Edamura (Jpn. J. Appl. Phys., Part 1 42, 7547 (2003)).

### SUMMARY OF THE INVENTION

In the apparatus shown in the above-described JP-A-2000-323298, the insulating-material manufactured window which is of cylinder shape or dome shape is used. The capacitively coupled antenna is also of cylinder shape, truncated-circular cone shape, or dome shape. The experiment made by the inventors et al. has clarified the following finding: In the inductively-coupled plasma processing apparatus equipped with the cylinder-shaped, truncated circular cone-shaped, or dome-shaped capacitively coupled antenna like this, applying the high voltage to the capacitively coupled antenna converts the plasma density distribution at the wafer position into a convex distribution.

Here, FIG. 2 is a diagram for explaining a plasma processing apparatus using a truncated circular cone-shaped capacitively coupled antenna 11. FIG. 3 is a plan view of the truncated circular cone-shaped antenna 11 used in the plasma processing apparatus illustrated in FIG. 2. FIG. 4 is a diagram for illustrating the plasma density distribution in the plasma processing apparatus illustrated in FIG. 2.

In these diagrams, a processing chamber 1 includes a pumping unit 2 and a transportation system 4 for transporting a semiconductor wafer 3, i.e., a specimen to be processed, into/from the processing chamber.

An electrode or stage 5 for mounting the semiconductor wafer 3 thereon is set inside the processing chamber 1. The wafer 3 is transported into the processing chamber by the transportation system 4 via a transporting gate valve 17. Moreover, the wafer 3 is conveyed onto the electrode 5, then being held by being electrostatically chucked by an electrostatic chuck formed on the top surface of the electrode (not illustrated). A radio-frequency power supply 9 with a several-hundred-KHz to several-tens-of-MHz frequency is connected to the electrode 5 via a matching unit or matcher 8.

The upper surface of the electrode 5 other than the wafer-mounting surface is usually protected from the plasma and reactive gases by an insulating-material manufactured electrode cover 7. Process-gas inlet 18 is provided below an insulating-material manufactured window 6 on the side surfaces of upper portion of the processing chamber. A process gas used for the processing is introduced into the processing chamber via the gas-inlet 18.

Meanwhile, a plasma generation unit based on the inductively coupled scheme is located at a position opposed to the wafer 3. Namely, an inductively coupled antenna 10 is located on the opposed surface to the wafer 3 on the atmospheric side via the insulating-material manufactured window 6 formed of an insulating material such as quartz or alumina ceramic. Also, the truncated circular cone-shaped capacitively coupled antenna 11 is set between the inductively coupled antenna 10 and the insulating-material manufactured window 6. Also, as illustrated in FIG. 3 as the plan view, the truncated circular cone-shaped capacitively coupled antenna 11 includes slits in a radial pattern, and is located such that the antenna 11 is in contact with the insulating-material manufactured window 6.

The truncated circular cone-shaped capacitively coupled antenna 11 is electrically connected via a fixed capacitor 12 to line of the radio-frequency power supplied to the inductively coupled antenna 10 via a matching unit 15. This connection makes it possible to provide the radio-frequency voltage thereto.

In the plasma processing apparatus having the configuration like this, when the high voltage is not applied to the truncated circular cone-shaped antenna 11, it is possible to acquire a flat plasma density distribution at the wafer position. However, if, in the plasma processing, the high voltage is applied to the capacitively coupled antenna 11, the plasma will be concentrated on central position of the wafer as is illustrated in FIG. 4. Also, if the voltage applied to the capacitively coupled antenna is increased, electric potential of the entire plasma varies significantly as is the case with the parallel-flat-plate plasma processing apparatus. In the case of the truncated circular cone-shaped capacitively coupled antenna 11, however, the antenna is of the truncated circular cone shape unlike the parallel-flat-plate plasma processing apparatus. As a result, it can be considered that the plasma will be concentrated on the proximity to the wafer's central position by the electric-potential variation in the entire plasma.

Also, if, as illustrated in FIG. 2, the inductively coupled antenna 10 is located along the capacitively coupled antenna 11, the plasma density distribution at the wafer position becomes ununiform because of the current loss to the electrostatically coupled antenna. As a consequence, the etching rate distribution becomes ununiform in the azimuthal direction (i.e., the plasma and the rate become biased).

Namely, it cannot be avoided from configuration-based requirements that the inductively coupled antenna 10 and the capacitively coupled antenna 11 be located in close proximity to each other. At this time, however, a stray capacitance between these antennas causes an electric current to flow from the inductively coupled antenna 10 to the capacitively coupled antenna 11. In particular, in a high-voltage portion of the inductively coupled antenna 10, the electric current flowing from the inductively coupled antenna 10 to the capacitively coupled antenna 11 is increased in amount. Consequently, an electric current which flows through the inductively coupled antenna 10 is decreased in amount (refer to FIG. 7). This, as described above, makes the plasma density distribution ununiform, and thus makes the etching rate distribution ununiform in the azimuthal direction.

The present invention has been devised in view of these problems. Accordingly, an object of the present invention is to provide a plasma processing apparatus which is capable of generating a stable and uniform plasma.

In order to solve the above-described problems, the plasma processing apparatus according to the present invention includes the following configuration components: A processing chamber whose one surface is formed by a flat-plate-like insulating-material manufactured window, a sample mounting electrode in which a sample mounting plane is formed on a surface opposed to the insulating-material manufactured window of the processing chamber, a gas inlet for introducing a processing gas into the processing chamber, a flat-plate-like capacitively coupled antenna formed on an outer surface of the insulating-material manufactured window with slits provided in a radial pattern, and an inductively coupled antenna formed outside the insulating material manufactured window and performing an inductive coupling with a plasma via the window, the plasma being generated within the processing chamber. Here, the inductively coupled antenna is configured by a coil which is wound a plurality of times with a direction defined as a longitudinal direction, the direction being perpendicular to the sample mounting plane.

Other objects, features and advantages of the invention will become apparent from the following description of the embodiments of the invention taken in conjunction with the accompanying drawings.

### BRIEF DESCRIPTION OF THE DRAWINGS

FIG. 1 is a diagram for explaining a plasma processing apparatus according to a first embodiment of the present invention;

FIG. 2 is the diagram of the prior art of the plasma processing apparatus using the truncated circular cone-shaped capacitively coupled antenna;

FIG. 3 is the plan view of the truncated circular cone-shaped antenna 11 used in the plasma processing apparatus illustrated in FIG. 2;

FIG. 4 is the diagram for illustrating the plasma density distribution at a wafer position in the plasma processing apparatus illustrated in FIG. 2;

FIG. 5 is a diagram for illustrating a plasma processing apparatus including a flat-plate-configured capacitively coupled antenna and an inductively coupled antenna located along therewith;

FIG. 6A and FIG. 6B are schematic diagrams for illustrating stray capacities along the inductively coupled antenna;

FIG. 7 is the schematic diagram for illustrating the current loss caused by the stray capacitance between the inductively coupled antenna and the Faraday shield;

FIG. 8 is a schematic diagram for illustrating a system of experiment and calculation for estimating influences of the stray capacitance between the inductively coupled antenna and the Faraday shield on the plasma;

FIG. 9A and FIG. 9B are schematic diagrams for illustrating experimental results of the ununiformity of plasma and calculation results of the ununiformity of electric current flowing through the inductively coupled antenna;

FIG. 10 is a perspective view for illustrating structure of the inductively coupled antenna;

FIG. 11A and FIG. 11B are schematic diagrams for illustrating an induced magnetic field generated by the inductively coupled antenna having a two-dimensional structure and an induced magnetic field generated by the inductively coupled antenna having the three-dimensional structure, respectively;

FIG. 12 is a diagram for explaining another embodiment of the present invention;

FIG. 13 is a diagram for explaining a still another embodiment of the present invention;

FIG. 14 is a diagram for explaining an even further embodiment of the present invention;

FIG. 15 is a diagram for explaining details of a structure that inner-side coil and outer-side coil intersect with each other; and

FIG. 16 is a diagram for explaining a coil-structured inductively coupled antenna according to another embodiment of the present invention.

### DETAILED DESCRIPTION OF THE EMBODIMENTS

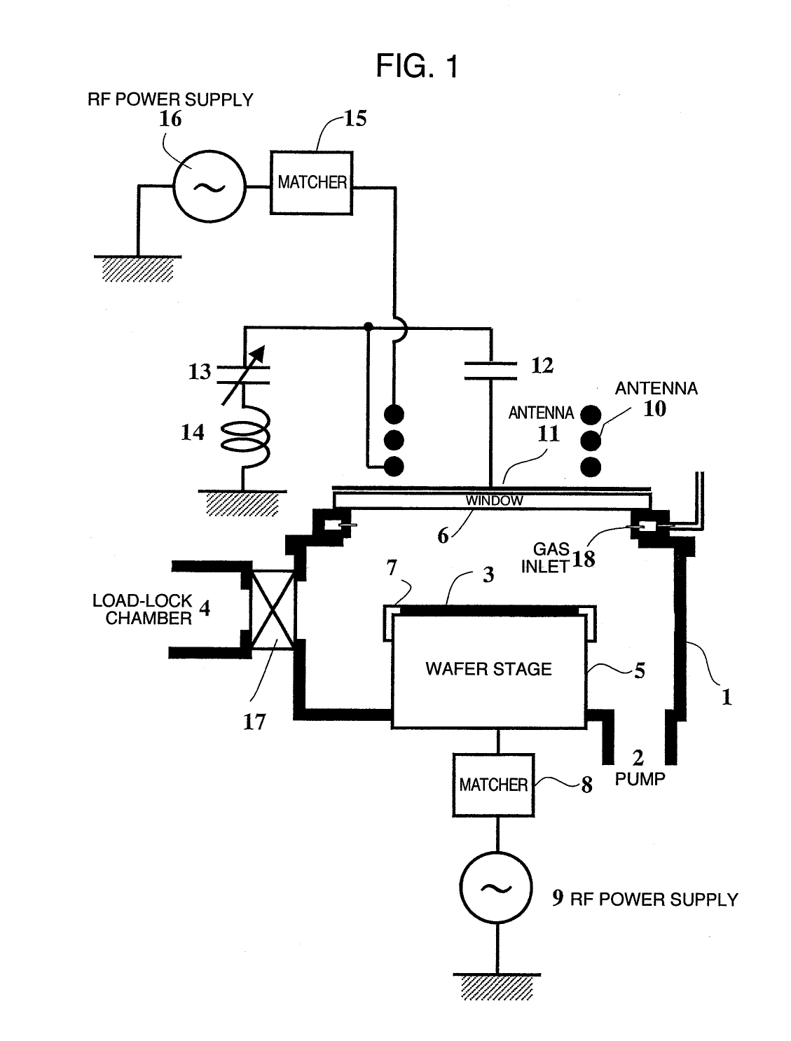

Hereinafter, referring to the accompanying drawings, the explanation will be given below concerning the best embodiments. FIG. 1 is a diagram for explaining a plasma processing apparatus according to the first embodiment of the present invention. In FIG. 1, a processing chamber 1 is, e.g., an aluminum-formed or stainless-formed vacuum container whose surface is subjected to an anodized processing. The processing chamber 1 is electrically grounded, and includes a pumping unit 2 and a transportation system 4 for transporting a semiconductor wafer 3, i.e., a specimen to be processed, into/from the processing chamber.

An electrode or stage 5 for mounting the semiconductor wafer 3 thereon is set inside the processing chamber 1. The wafer 3 is transported into the processing chamber by the transportation system 4 via a transporting gate valve 17. Moreover, the wafer 3 is conveyed onto the electrode 5, then being held by being chucked by a not-illustrated electrostatic chuck. A radio-frequency power supply 9 with a several-hundred-KHz to several-tens-of-MHz frequency is connected to the electrode 5 via a matching unit 8. This connection is established in order to control energy of the ions incoming into the semiconductor wafer 3 during the plasma processing. Furthermore, within the electrode 5, although not illustrated, there is provided a flow path of a coolant for keeping constant the temperature of the under-processing wafer heated by the plasma. Also, if it is required to maintain the wafer at a high temperature, there is provided a built-in heater.

The upper surface of the electrode 5 other than the wafer-mounting surface is usually protected from the plasma and reactive gases by an insulating-material manufactured electrode cover 7. Process-gas inlet 18 is provided directly below a flat-plate-like insulating-material manufactured window 6 formed on the upper portion of the processing chamber. A process gas used for the processing is introduced into the processing chamber via the gas-inlet 18.

Meanwhile, a plasma generation unit based on the inductively coupled scheme is located at a position opposed to the wafer 3. Namely, an inductively coupled antenna 10 is located on the opposed surface to the wafer 3 on the atmospheric side via the flat-plate-like insulating-material manufactured window 6 formed of an insulating material such as quartz or alumina ceramic. Here, the inductively coupled antenna 10 is configured by a coil which is wound a plurality of times with a direction defined as a longitudinal direction, the direction being perpendicular to a sample mounting plane of the electrode 5 (namely, the antenna 10 has a three-dimensional structure). Also, a flat-plate-like capacitively coupled antenna 11 is set between the inductively coupled antenna 10 and the insulating-material manufactured window 6.

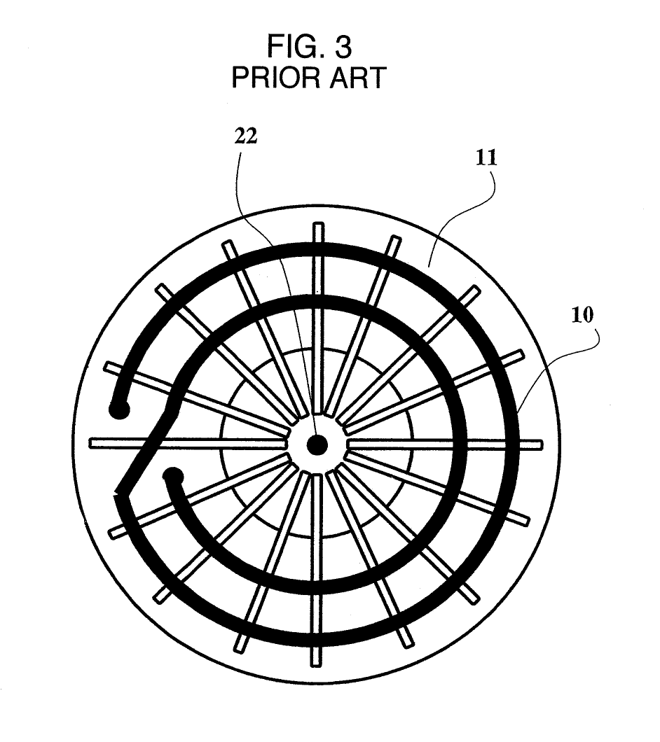

The capacitively coupled antenna 11 is a flat plate formed of an electrically conductive material. As is the case with the truncated circular cone-shaped capacitively coupled antenna 11 explained in FIG. 3 as the plan view, the flat-plate-like capacitively coupled antenna 11 includes slits in a radial pattern, and is located such that the antenna 11 is in contact with the insulating-material manufactured window 6.

The above-described slits are formed in a radial pattern such that the slits will cut across loops of the inductively coupled antenna 10. This permits an induced current induced by the inductively coupled antenna 10 to flow over to the plasma (if it were not for the slits, the induced current would flow over to the capacitively coupled antenna 11). The capacitively coupled antenna 11 is electrically connected via a fixed capacitor 12 to line of a radio-frequency power supplied to the inductively coupled antenna 10. This connection makes it possible to provide the radio-frequency voltage thereto. The voltage applied to the capacitively coupled antenna 11 is configured such that the voltage can be adjusted by varying electrostatic capacitance of a variable capacitor 13. Namely, when the variable capacitor 13 and a fixed inductance 14 have come to satisfy the condition of series resonance, the capacitively coupled antenna 11 can be assumed to have been substantially shorted to the ground potential. At this time, the voltage at the capacitively coupled antenna 11 becomes nearly equal to zero.

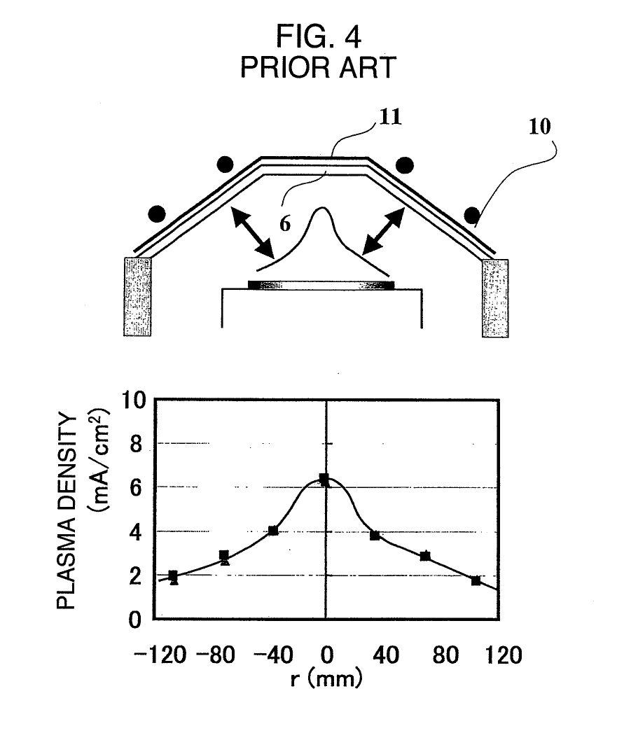

In the case like this, the capacitively coupled antenna 11 operates in basically the same manner as the generally-known Faraday shield does. Then, if the variable capacitor 13 is adjusted so as to disengage the variable capacitor from the series resonance state, the radio-frequency voltage is applied to the capacitively coupled antenna 11. This voltage accelerates ions within the plasma up onto an inner surface of the insulating-material manufactured window 6. Then, ion bonbardment resulting therefrom makes it possible to prevent the deposition of reaction-products on the inner surface of the window 6. Also, as illustrated in FIG. 1, the capacitively coupled antenna 11 is formed into the flat-plate configuration. This flat-plate configuration results in none of the concentration of plasma density at the central position as was illustrated in FIG. 4. As a consequence, even if the high voltage has been applied to the capacitively coupled antenna 11, it becomes possible to acquire excellent plasma density distribution and etching rate distribution.

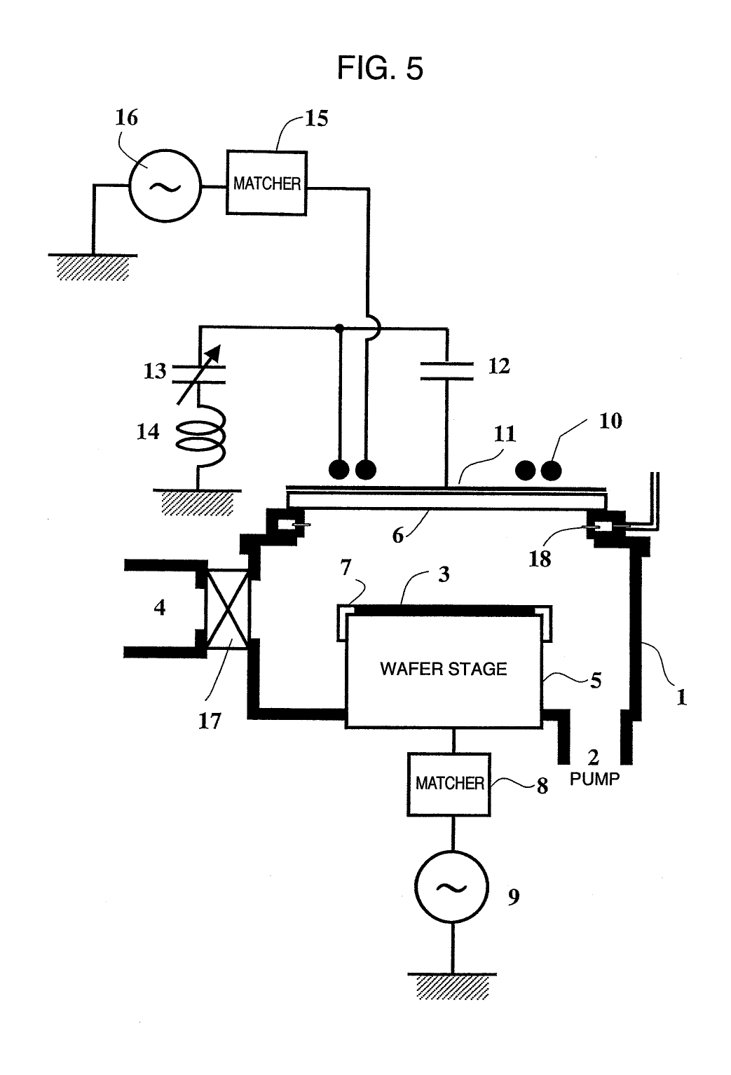

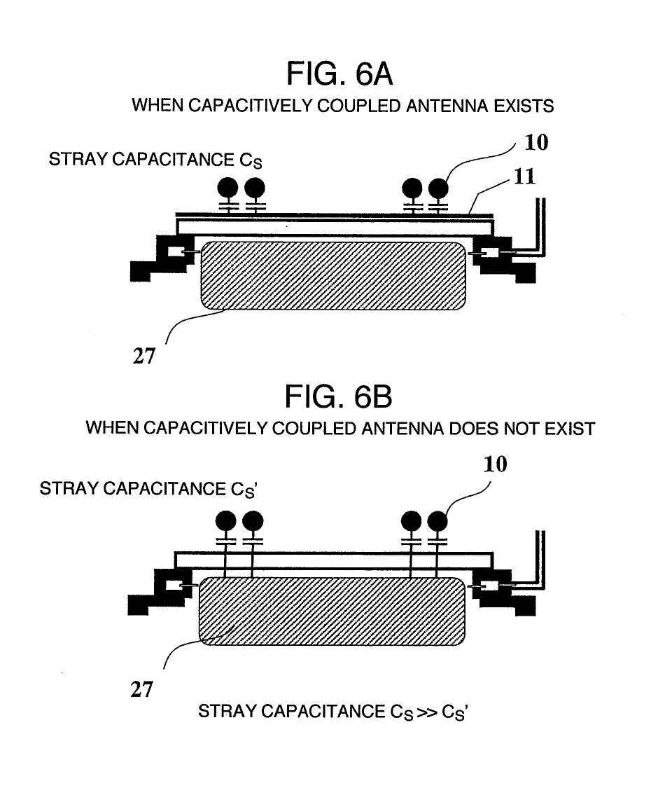

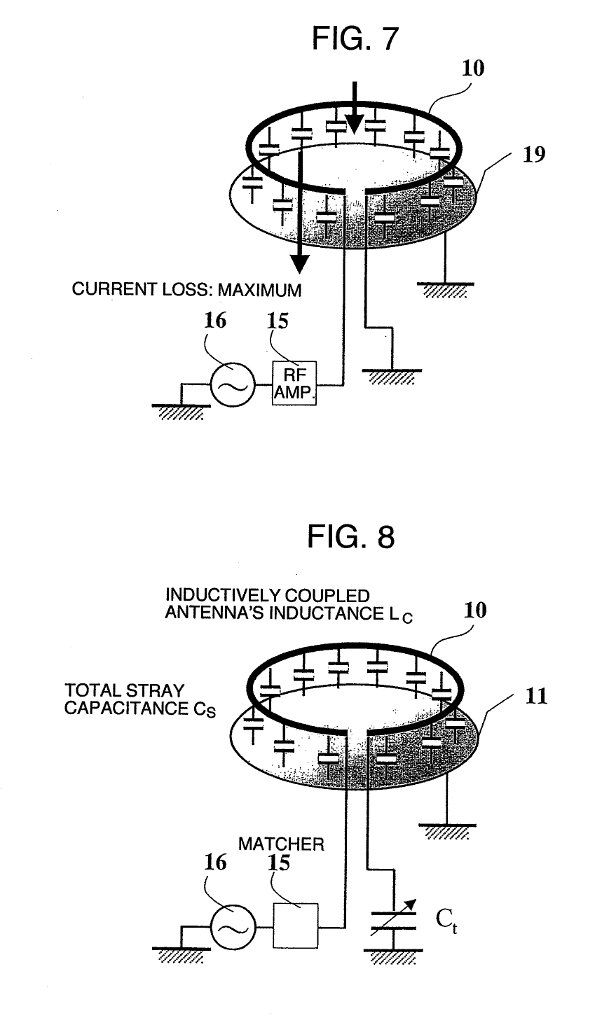

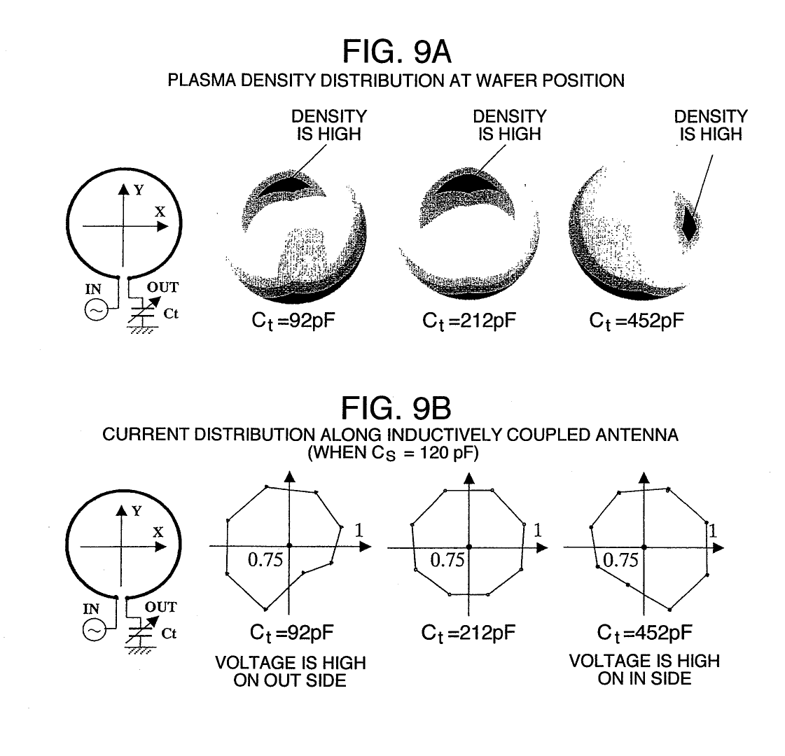

As having been described above, the characteristic of the above-described first embodiment is the combination of the inductively coupled antenna 10 having the three-dimensional structure and the flat-plate-like capacitively coupled antenna 11. Hereinafter, referring to FIG. 5 to FIG. 9, the explanation will be given below concerning superiority of this combination. FIG. 5 is a diagram for illustrating a plasma processing apparatus including the flat-plate-configured capacitively coupled antenna and the inductively coupled antenna located along therewith. FIG. 6A and FIG. 6B are schematic diagrams for illustrating stray capacities along the inductively coupled antenna. FIG. 7 is the schematic diagram for illustrating the current loss caused by the stray capacitance between the inductively coupled antenna and the Faraday shield. FIG. 8 is a schematic diagram for illustrating a system of experiment and calculation for estimating influences of the stray capacitance between the inductively coupled antenna and the Faraday shield on the plasma. FIG. 9A and FIG. 9B are schematic diagrams for illustrating calculation results of the ununiformity of current flowing through the inductively coupled antenna occurring from the current loss caused by the stray capacitance between the inductively coupled antenna and the Faraday shield, and experimental results of the ununiformity of plasma.

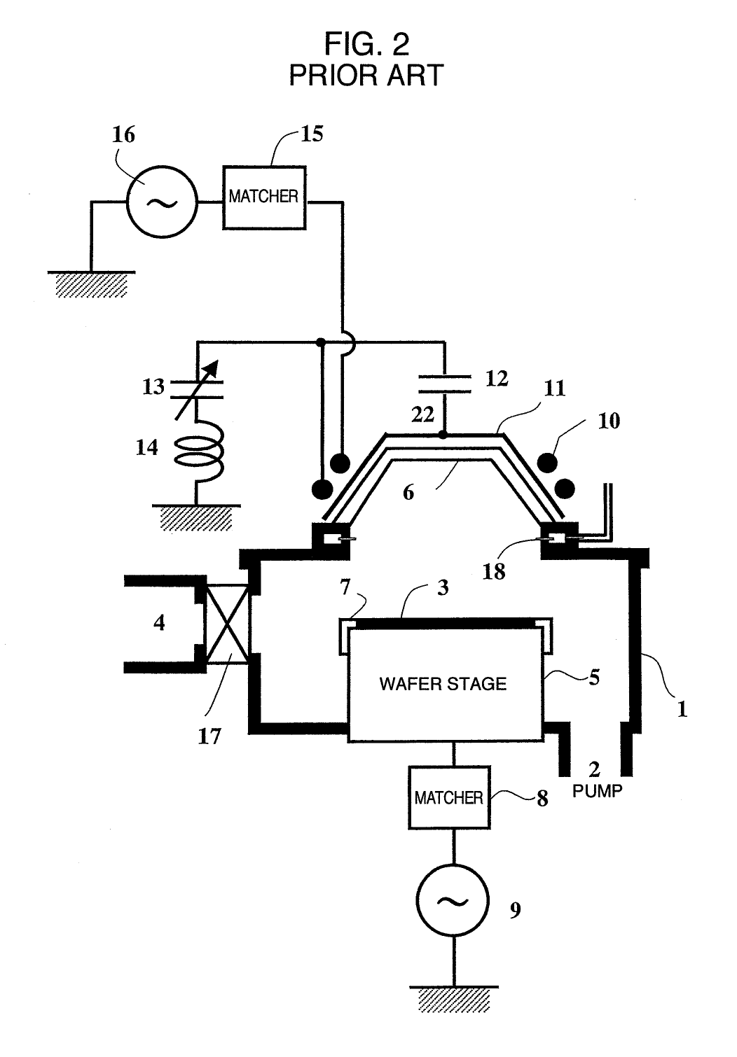

Consider a case of modifying the truncated circular cone-shaped discharge unit as illustrated in FIG. 2 into the flat-plate shape with no modification added to the other configuration components. This modification, usually, results in acquisition of the structure as illustrated in FIG. 5. In the plasma apparatus illustrated in FIG. 5 as well as in the one illustrated in FIG. 2, the two-turn loop of the inductively coupled antenna 10 is so structured as to be in close proximity to the electrostatically-capacitively coupled antenna 11. The structure like this, however, causes a bias in a predetermined direction to occur in the plasma density distribution and the etching rate distribution. The reason for this will be explained below, using FIG. 6A, FIG. 6B, and FIG. 7. Incidentally, the problem of this bias is basically the same as in the general Faraday shield, which can be considered as the case where the capacitively coupled antenna 11 is connected to the ground potential. Accordingly, for simplicity here, the above-described reason will be explained, assuming that the capacitively coupled antenna 11 is the Faraday shield at the ground potential.

The radio-frequency wave, which, eventually, is the high voltage, is applied to the inductively coupled antenna 10. Since the inductively coupled antenna 10 is positioned in close proximity to the Faraday shield, an unintentional stray capacitance is formed between the antenna 10 and the Faraday shield. In the general inductively coupled plasma apparatus where there is provided none of the capacitively coupled antenna 11, a stray capacitance exists between the plasma and the inductively coupled antenna 10 (FIG. 6B). This is because the plasma can be regarded as an electrically conductive material. In the case of the plasma apparatus where there is provided the Faraday shield, however, this stray capacitance is comparatively large (FIG. 6A). This is because the inductively coupled antenna 10 and the Faraday shield are positioned in close proximity to each other.

Although the high voltage is generated at the inductively coupled antenna 10, the value of this voltage (peak-to-peak voltage) is not constant along the loop of the inductively coupled antenna 10. Here, consider a simple system as is illustrated in FIG. 7. This is the simplest case where the system includes the one-loop inductively coupled antenna 10 and a Faraday shield 19 located in close proximity thereto. In this case, the voltage of the inductively coupled antenna 10 becomes its maximum value on the radio-frequency power-supply side, zero on the ground-potential side, and one-half of the maximum voltage at the intermediate point therebetween. Consequently, if it is assumed that the stray capacitance is uniformly distributed along the inductively coupled antenna 10, the current loss becomes its maximum value on the radio-frequency power-supply side. This, eventually, causes the plasma density distribution to be biased on the ground-potential side.

For implementing a further detailed consideration, as illustrated in FIG. 8, a variable capacitor is inserted on the ground-potential side of the one-loop inductively coupled antenna 10, and then the capacitance Cₜ of this variable capacitor is varied. Namely, varying the capacitance Cₜ makes it possible to vary the distribution of the voltage occurring at the inductively coupled antenna 10. Here, let inductance of the inductively coupled antenna 10 and frequency of the radio-frequency wave be L_{C} and f, respectively. Then, in a value of the capacitance Cₜ given when 1/(2nfCₜ)=(1/2)(2nfL_{C}) holds, the voltages at both ends of the inductively coupled antenna 10 become equal to each other, and the voltage becomes equal to zero at the exactly intermediate point of the inductively coupled antenna 10. When the capacitance Cₜ is larger than this value, the voltage becomes higher on the radio-frequency power-supply side. Meanwhile, when the capacitance Cₜ is smaller than this value, the voltage becomes higher on the ground-potential side.

FIG. 9A and FIG. 9B respectively illustrate variations in the plasma density distribution at the wafer position when the capacitance Cₜ is varied, and distributions in calculation value of (in the case of the total stray capacitance C_{S}=120 pF) electric current flowing along the inductively coupled antenna 10 at that time. These drawings have clearly shown the following phenomena: The stray capacitance between the inductively coupled antenna 10 and the Faraday shield causes the distributions to occur in the electric current flowing to the inductively coupled antenna 10. This phenomenon, further, causes the bias to occur in the plasma density distribution.

In this way, the bias in the plasma density distribution is caused by the stray capacitance between the inductively coupled antenna 10 and the Faraday shield. Here, it can be easily considered that a method for eliminating the bias in the plasma like this is to lower the voltage occurring at the inductively coupled antenna 10 and to locate the inductively coupled antenna 10 away from the Faraday shield. However, this kind of method for eliminating the bias in the plasma lowers plasma's ignition quality, stability, and plasma generation ratio.

For example, as described in a research paper (J. Vac. Sci. Technol. A 22, 293 (2004).) by one of the inventors, Edamura, et al., the following finding has been known. In the inductively coupled plasma apparatus, at the ignition time or at a low-power time, the capacitively coupled discharge caused by the voltage at the inductively coupled antenna supports and maintains the plasma. The setting of the Faraday shield means cutting of this capacitively coupled discharge caused by the voltage at the inductively coupled antenna. Accordingly, it is impossible to start the discharge unless the voltage at the inductively coupled antenna is so set as to be leaked to the plasma to some extent. Also, the setting of the Faraday shield between the inductively coupled antenna and the plasma decreases the coupling between the inductively coupled antenna and the plasma. Consequently, from this viewpoint as well, the location of the inductively coupled antenna away from the Faraday shield gives rise to a problem. Also, it can be considered that increasing the turn number of the inductively coupled antenna is effective for reducing the bias. This, however, increases the inductance of the antenna, thereby becoming a trade-off in relation to the lowering of the voltage at the inductively coupled antenna.

Meanwhile, U.S. Pat. No. 5,711,998 and U.S. Pat. No. 6,462,481 have disclosed a plasma apparatus where, instead of merely locating the antenna away from the Faraday shield, an inductively coupled antenna having a longitudinal structure (i.e., longitudinally wound) is located on a flat-plate-like insulating-material manufactured window. Employing the structure like this causes upper loops to be positioned away from the Faraday shield, although the bottom loop is positioned in close proximity thereto. As a result, it can be considered that the current loss caused by the stray capacitance will be reduced, and that it becomes possible to acquire an effect of improving the bias in the plasma. Exactly as described earlier, however, the setting of the Faraday shield results in apprehension of the problems of the plasma's ignition quality and stability.

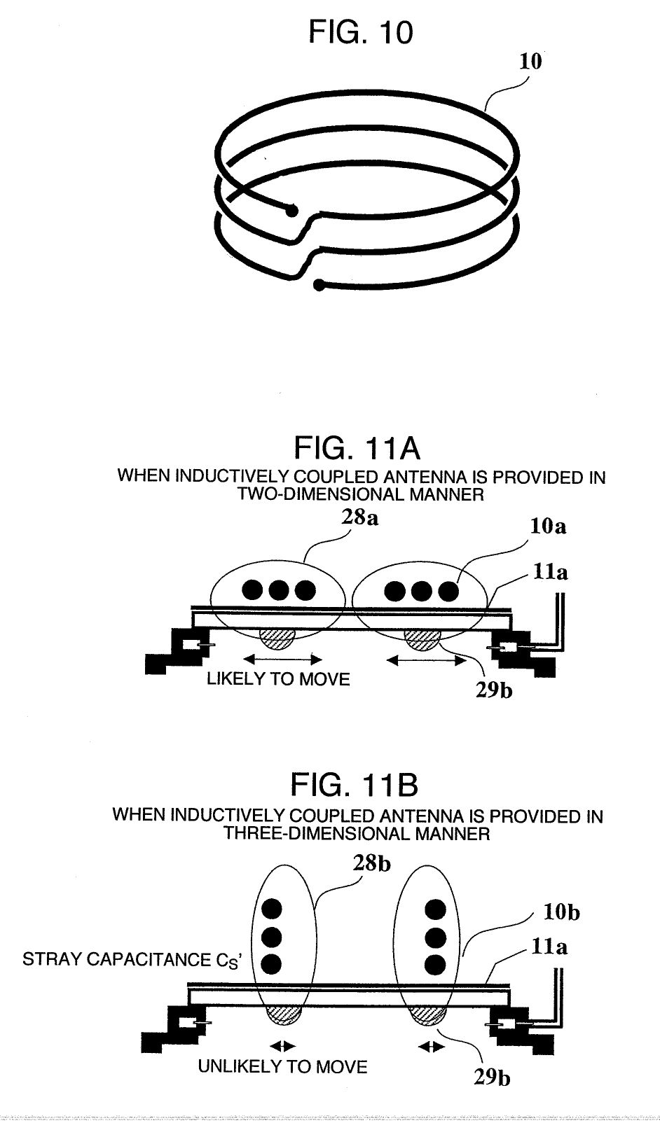

In the above-described first embodiment, however, it is possible to make variable the voltage at the capacitively coupled antenna 11, not the voltage at the Faraday shield fixed onto the ground potential. Accordingly, it becomes possible to compensate the discharge stability at the ignition time or at the low-power time by increasing the voltage to the capacitively coupled antenna 11. This is because, at the ignition time or at the low-power time, the voltage at the capacitively coupled antenna works as an alternative to the role played by the voltage at the inductively coupled antenna of the usual plasma apparatus. Consequently, as illustrated in FIG. 10, even if the inductively coupled antenna is used which is configured by the coil wound a plurality of times with the direction defined as the longitudinal direction, the direction being perpendicular to the sample mounting plane, it becomes possible to clear the problems of the ignition quality and discharge stability.

Effects acquired by configuring the inductively coupled antenna 10 into the three-dimensional structure are not only the above-described effect of reducing the current loss caused by the stray capacitance. FIG. 11A and FIG. 11B are schematic diagrams for illustrating an induced magnetic field 28a generated by an inductively coupled antenna 10a having a two-dimensional structure and an induced magnetic field 28b generated by the inductively coupled antenna 10b having the three-dimensional structure, respectively. It has been known that resultant plasmas are mainly generated at positions which are directly below the insulating-material manufactured window 6 and at which these induced magnetic fields become the strongest. FIG. 11A has clearly shown that, in the case of the inductively coupled antenna 10a having the two-dimensional structure, the magnetic field 28a generated directly below the insulating-material manufactured window 6 is comparatively flat. Here, although the entire magnetic field is comparatively flat, much of the plasma 29a turns out to be generated in a diameter where the magnetic field is the strongest. In this case, however, if the magnetic field is biased due to factors such as the above-described current loss caused by the stray capacitance, the plasma-generated position becomes likely to move. Meanwhile, in the case of the inductively coupled antenna 10b having the three-dimensional structure, the plasma-generated position 29b is unlikely to be biased. This is because a diameter where the induced magnetic field 28b is the strongest is fixed.

The etching of the above-described non-volatile material film is performed by using the combination of the flat-plate-structured capacitively coupled antenna 11 and the inductively coupled antenna 10 having the three-dimensional structure as illustrated in FIG. 1. This method, consequently, allows implementation of the following performances: (1) the ignition and discharge can be stabilized, (2) a large number of wafers can be processed stably while preventing deposition of the reaction products by applying the high voltage to the capacitively coupled antenna, (3) the plasma will not be concentrated on the center even in the state where the high voltage is applied, and the uniform plasma generation and etching rate distribution can be acquired in the diameter direction, and (4) there exists none of the bias in the plasma at a wafer position, and the uniform etching rate distribution can be acquired in both of the radial and azimuthal directions. Namely, the plasma processing apparatus having the structure as illustrated in FIG. 1 allows accomplishment of all the performances indicated in (1) to (4).

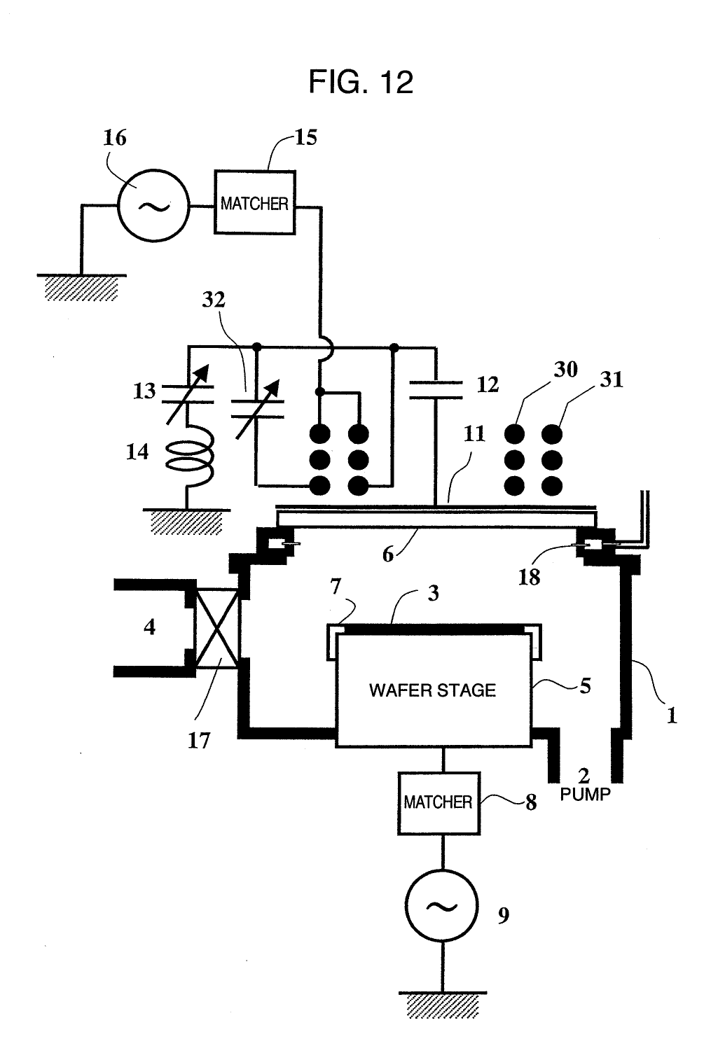

FIG. 12 is a diagram for explaining another embodiment of the present invention. In the plasma etching apparatus, in some cases, making fine adjustment of the plasma distribution is required. Accordingly, in the embodiment illustrated in FIG. 12, there is provided an inductively coupled antenna (30, 31) formed with a two-system coil including an inner-side coil and an outer-side coil. In circuit terms, the inductively coupled antenna 30 formed with the inner-side coil and the inductively coupled antenna 31 formed with the outer-side coil are connected in parallel. In the case like this, more current tends to flow to the antenna having a smaller impedance. As a result, if the inner-side and outer-side antennas are formed with equal turn-number coils, more current will flow to the inner-side antenna with a smaller loop. Accordingly, in order to adjust the currents flowing through the inner-side and outer-side coils, a variable capacitor 32, which is an impedance controller, is provided in series with the outer-side coil.

In this way, by changing the current ratio between the inner side and the outer side, it becomes possible to make the fine adjustment of the plasma density distribution or etching rate distribution. At this time, lengthening the distance between the inner-side coil and the outer-side coil too much causes a state to occur which is similar to the one illustrated in FIG. 11A where the antenna is wound in the two-dimensional manner. This makes it likely that the distribution will be biased. The distance between the inner-side coil and the outer-side coil is determined by a trade-off between an adjustment range of the plasma distribution wished to be acquired and a tolerance limit to the bias in the distribution.

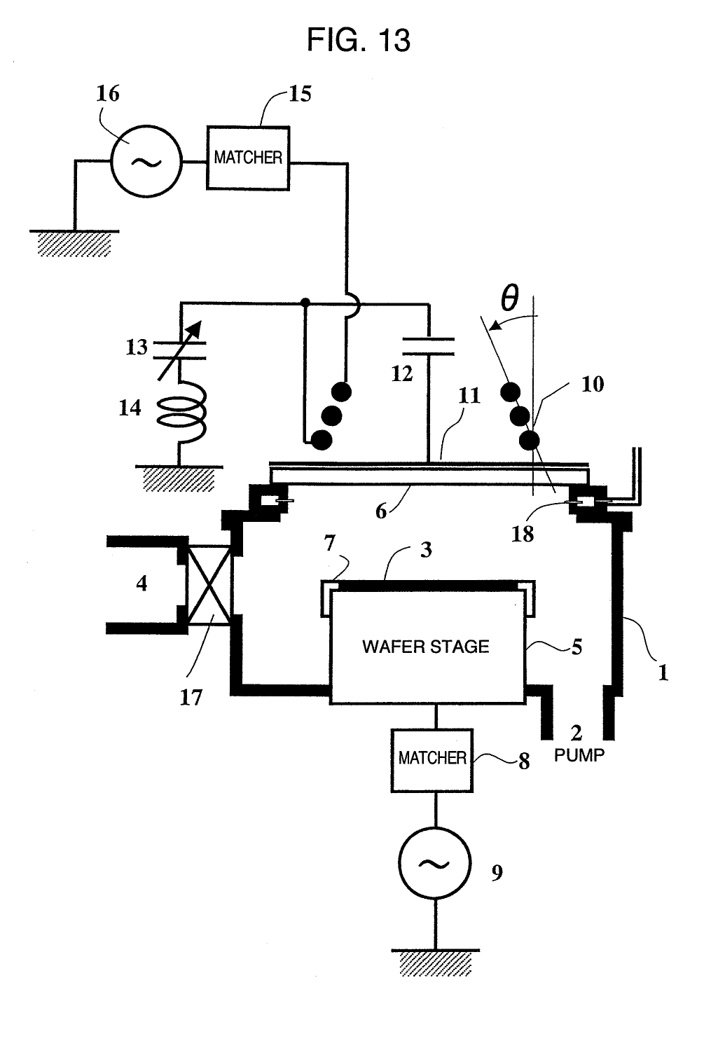

FIG. 13 is a diagram for explaining a still another embodiment of the present invention. The inductively coupled antenna 10 is not necessarily required to have the structure which is completely vertical to the capacitively coupled antenna 11 or the wafer 3. Namely, as illustrated in FIG. 13, the antenna 10 is also allowed to have an inclined structure (i.e., truncated circular cone- or inversed-truncated circular cone-structure). The inclination angle (θ) brings about effects which are not so significantly different as those of the embodiment illustrated in FIG. 1. This holds as long as the inclination angle falls within substantially ±45° (when direction of the arrow in FIG. 13 is defined as being positive).

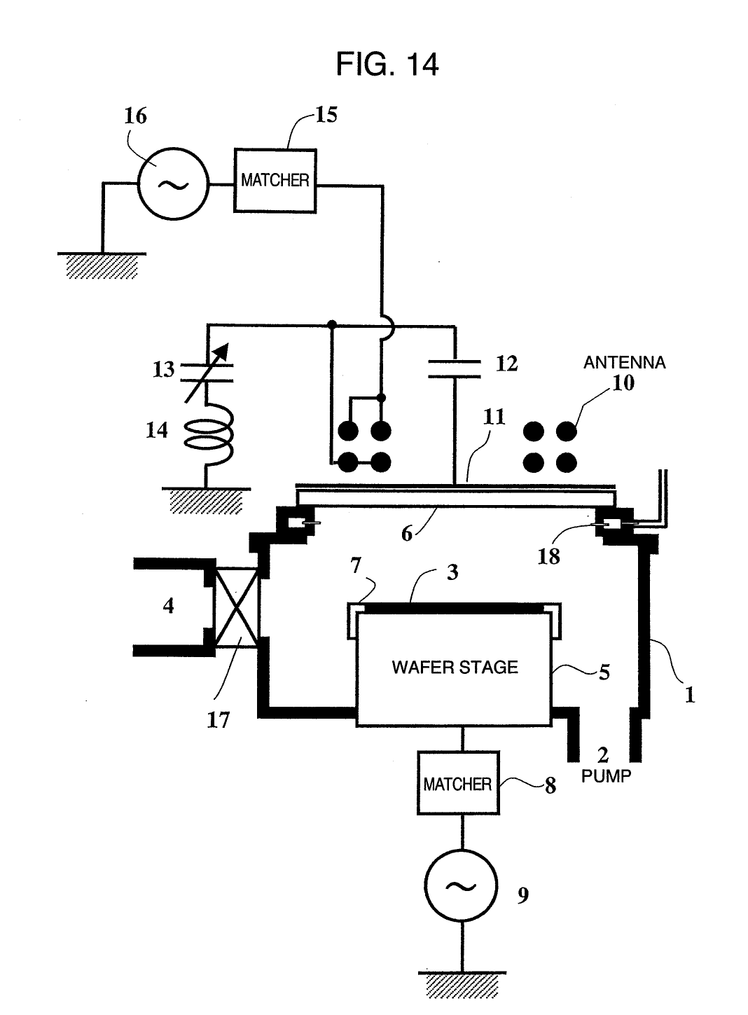

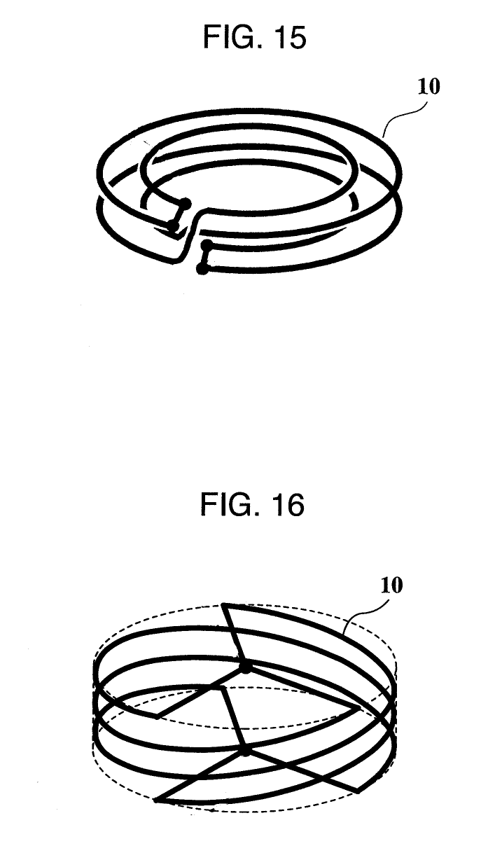

FIG. 14 and FIG. 15 are diagrams for explaining an even further embodiment of the present invention. This embodiment has a two-column structure that the inner-side coil and the outer-side coil intersect with each other. As explained in FIG. 12, it is preferable that the distance between the inner-side and outer-side antennas be not so long. FIG. 15 is the diagram for explaining details of the structure that the inner-side and outer-side coils intersect with each other. An object of causing the inner-side and outer-side coils to intersect with each other is that inductances of the coils connected in parallel in the two-system coil are made substantially equal to each other.

Concerning the structure of the inductively coupled antenna, as explained above, the structure of the inductively coupled antenna can be implemented in the manners that the coils configuring the antenna are caused to intersect with each other, are connected in parallel, or are wound with an inclination added thereto.

FIG. 16 is a diagram for explaining a still further embodiment of the present invention. In the embodiment in this diagram, in substitution for the coil which is illustrated in FIG. 10 and is wound a plurality of times in a cylinder-like manner with the direction defined as the longitudinal direction, the direction being perpendicular to the sample mounting plane, the inductively coupled antenna is configured by connecting in parallel a plurality of coils (i.e., antenna elements) which are wound in a cylinder-like manner. This allows implementation of a further reduction in the bias in the current distribution, thereby making it possible to improve the uniformity in the azimuthal direction. In order to reduce the bias in the current distribution, as illustrated in FIG. 16, the following configuration is effective: Namely, the plurality of exactly the same antenna elements are arranged in parallel in circuit terms, then being set up on each constant-angle basis. Moreover, the plurality of antenna elements are connected to each other in parallel. This parallel connection, as is also apparent in electrical-circuit terms, reduces total inductance of the inductively coupled antenna including the plurality of antenna elements, thereby lowering the antenna voltage. This, eventually, makes it possible to reduce the current loss caused via the stray capacitance. Also, in the conventional apparatus, the voltage lowering gives rise to the problem that the ignition quality will be lowered. In the present invention, however, it is possible to suppress the lowering in the ignition quality by applying the voltage to the capacitively coupled antenna via the inductively coupled antenna. As a result, exactly as described earlier, none of this kind of problems occurs in the present invention.

As having been explained so far, according to the present invention, it becomes possible to implement the following performances: (1) the ignition and discharge can be stabilized, (2) a large number of wafers can be processed stably while preventing deposition of the reaction products by applying the high voltage to the electrostatically-capacitively coupled antenna, (3) the plasma will not be concentrated on the center even in the state where the high voltage is applied to the electrostatically-capacitively coupled antenna, and thus the uniform plasma is generated in the diameter direction, and thereby the uniform etching rate distribution can be acquired, and (4) there exists none of the bias in the plasma, and the uniform etching rate distribution can be implemented in the azimuthal direction.

On account of this, when performing the plasma processing to the samples such as the novel semiconductor devices using the non-volatile materials which will produce the large amount of deposited reaction products, it becomes possible to perform stable plasma processing in a long term of mass-production.

It should be further understood by those skilled in the art that although the foregoing description has been made on embodiments of the invention, the invention is not limited thereto and various changes and modifications may be made without departing from the spirit of the invention and the scope of the appended claims.

1. A plasma processing apparatus, comprising:
a processing chamber of which one surface is formed by a flat-plate-like insulating-material manufactured window;
a sample mounting electrode in which a sample mounting plane is formed on a surface opposed to said insulating-material manufactured window of said processing chamber;
a gas-inlet which introduces a processing gas into said processing chamber;
a flat-plate-like capacitively coupled antenna formed on an outer surface of said insulating-material manufactured window with slits provided in a radial pattern;
an inductively coupled antenna formed outside of said insulating-material manufactured window and performing an inductive coupling with a plasma via said window, said plasma being formed within said processing chamber;
a radio-frequency power supply which supplies radio-frequency power to said inductively coupled antenna; and
an LC circuit which controls a radio-frequency voltage supplied to said flat-plate-like capacitively coupled antenna from said radio-frequency power supply via said inductively coupled antenna;
wherein said flat-plate-like capacitively coupled antenna is disposed between said flat-plate-like insulating-material manufacturing window and said inductively coupled antenna;
wherein said LC circuit is coupled to said flat-plate-like capacitively coupled antenna and said inductively coupled antenna; and
wherein said inductively coupled antenna is a coil which is wound a plurality of times with a direction defined as a longitudinal direction, the direction extending perpendicular to said sample mounting plane.

2. The plasma processing apparatus according to claim 1, wherein said coil configuring said inductively coupled antenna is formed by connecting in parallel a plurality of coaxially would coils.

3. The plasma processing apparatus according to claim 1,
wherein said coil configuring said inductively coupled antenna is formed by connecting in parallel a plurality of coaxially wound coils; and
wherein an impedance device for adjusting electric-current sharing among said plurality of coils is connected to at least one of said plurality of coils.

4. The plasma processing apparatus according to claim 1, wherein said coil configuring said inductively coupled antenna is wound in a truncated circular cone shape or in an inverted truncated circular cone shape.
